(19) United States
(12) Patent Application Publication
(10) Pub. No.: US 2011/0162290 A1
(43) Pub. Date: Jul. 7, 2011

(54) Photovoltaic Cell Support Assembly

(75) Inventors: Christopher G.E. Nightingale, Singapore (SG); Boon Hou Tay, Singapore (SG); Swee Ming Goh, Singapore (SG)

(73) Assignees: ALTERNATIVE ENERGY TECHNOLOGY PTE. LTD., Singapore (SG); DRAGON ENERGY PTE. LTD., Singapore (SG)

(21) Appl. No.: 12/904,116

(22) Filed: Oct. 13, 2010

(30) Foreign Application Priority Data
Oct. 13, 2009 (SG) 200906839-6

(51) Int. Cl. H01L 31/05; B21D 47/00; E04F 19/00

(52) U.S. Cl. 52/27; 136/251; 29/897.3

(57) ABSTRACT

A photovoltaic cell support assembly (10) comprises a first surface (32) provided with a plurality of recesses (14) configured to receive respective hooks (16) to facilitate hanging of the assembly (10) to a wall (18) to which the hooks (16) are attached. The assembly (10) is also provided with a second surface (13) configured to mechanically and electrically couple with one or more photovoltaic cells (24) and an electric circuit (22) supported by the assembly (10). The electrical circuit (22) is provided with a plurality of terminals (60) that extend through the second surface (13) to provide the mechanical and electrical coupling of the photovoltaic cells (24). The electric circuit (22) is configured to electrically connect the or each photovoltaic cell (24) coupled to the second surface together and to electrically connect the assembly (10) to a second like assembly (10).

### CROSS-REFERENCE TO RELATED PATENT APPLICATION

This application claims the benefit of Singapore Patent Application No. 200906839-6, filed on Oct. 13, 2009, the disclosure of which is incorporated herein in its entirety by reference.

### BACKGROUND OF THE INVENTION

1. Field of the Invention

The present invention relates to a photovoltaic cell support assembly, particularly although not exclusively, for attachment to a vertical wall to form a solar electric power generating cladding for the wall.

2. Background

Photovoltaic tiles and panels are increasingly used on the roofs of buildings to provide electrical energy to supplement the energy demands for the buildings and their occupiers. Such panels and tiles are often provided with a support structure that mimics the configuration of conventional roof coverings such as roof tiles and slates to enable attaching of the photovoltaic panels and tiles to the roof without substantive modification of the roof. However such photovoltaic panels and tiles are unsuitable for connection or coupling to a wall.

### SUMMARY OF THE INVENTION

One aspect of the invention provides a photovoltaic cell support assembly comprising:
a first surface provided with a plurality of recesses configured to receive respective hooks to facilitate hanging of the assembly to a wall to which the hooks are attached;
a second surface configured to mechanically and electrically couple with one or more photovoltaic cells; and,
an electric circuit supported by the assembly, the electrical circuit provided with a plurality of terminals that extend through the second surface to provide the mechanical and electrical coupling of the photovoltaic cells, the electric circuit configured to electrically connect the or each photovoltaic cell coupled to the second surface together and electrically connect the assembly to a second like assembly.

Each recess may be configured to prevent flow of a liquid into the interior of the assembly from the recess when the assembly is hung on a wall by the hooks.

Each recess may be sealed to prevent flow of a liquid into an interior of the assembly from the recess when the assembly is hung on a wall by the hooks.

The assembly may comprise a first panel wherein the first surface is a surface of the first panel which faces the wall when the assembly is hung on the wall, and wherein the recess comprises a recess surface which is continuous with the first surface.

The assembly may comprise respective lips extending laterally from each of two edges of the assembly and respective rebates provided about each of two further edges of the assembly, the lips and rebates being relatively configured wherein the lips on the assembly can seat in rebates of two respective adjacent assemblies.

At least one of the lips may be provided with a pre-formed hole for receiving a fastener, the hole located so that the fastener when applied through the hole couples the assembly to the rebate of an adjacent assembly.

The assembly may comprise a second panel wherein the second surface is an exposed surface of the second panel and wherein the second panel is coupled to and spaced from the first panel.

The electrical terminals may pass through the second layer and may be provided with blind holes that open onto the second surface for receiving connectors of the photovoltaic cells.

The electrical circuit may comprise a sub-circuit disposed in a space between the first panel and the second panel, the sub-circuit electrically connected to the electrical terminals and to electrical plugs, the electrical plugs facilitating electrical connection between adjacent assemblies.

The sub-circuit may be configured to couple the photovoltaic cells supported on a common second panel in series.

The sub-circuit may comprise for each photovoltaic cell, a bypass diode coupled across the electrical terminals to which that photovoltaic cell is connected.

The electrical plugs may be connected with the sub-circuit in a manner wherein adjacent assemblies are electrically coupled in series.

The assembly may comprise a frame disposed between the first panel and the second panel, the frame spacing the first panel from the second panel.

The first and second panels may be attached and sealed to the frame.

The first panel may be made of a thermally insulating material.

The second panel may be made of a thermal insulating material.

The first panel may be made of a fire proof material.

The second panel may be made of a fireproof material.

A second aspect of the invention provides a substantially vertical wall comprising:
a vertical wall surface;
a plurality of hooks fastened to the surface; and,
one or more assemblies according to the first aspect wherein the or each assembly is hung on the wall by engagement of one or more of the hooks with one or more of the recesses of the assemblies.

The wall may comprise a plurality of photovoltaic cells provided with connectors that project perpendicular to a plane of the cells, wherein the photovoltaic cells are coupled to the assemblies by engagement of the connectors with the terminals.

A third aspect of the invention may provide a method of constructing a substantially vertical solar electrical power generating wall comprising:
constructing a substantially vertical wall;
cladding the wall with a plurality of assemblies according to the first aspect by fastening a plurality of hooks on the wall, hanging the photovoltaic cladding assemblies on the hooks, and electrically connecting the assemblies together; and,
electrically and mechanically coupling a plurality of photovoltaic cells to the assemblies by insertion of connectors of the cells with the terminals of the assemblies.

### BRIEF DESCRIPTION OF THE DRAWINGS

FIG. 1 is an isometric view of a photovoltaic cell support assembly in accordance with an embodiment of the present invention;

FIG. 2 is an exploded view of the assembly shown in FIG. 1;

FIG. 2A is a detailed view of area A within FIG. 2;

FIG. 2B is a detailed view of area B shown in FIG. 2;

FIG. 2C is a detailed view of area C shown in FIG. 2;

FIG. 2D is a detailed view of area D shown in FIG. 2;

FIG. 2E is a view of section E-E of FIG. 2D;

FIG. 3A is a plan view of an electric circuit incorporated in the assembly;

FIG. 3B is a schematic representation of a portion of the electric circuit;

FIG. 3C is a circuit diagram of the electric circuit incorporated in the assembly;

FIG. 3D is an exploded view of an electric terminal and other components of the electric circuit;

FIG. 4 is a schematic representation of a vertical wall;

FIG. 4A is a representation of the wall with fitted hooks for receiving an assembly;

FIG. 4B is a detailed view of area B shown in FIG. 4A;

FIG. 4C illustrates how the assemblies are mounted on the wall;

FIG. 5 is a view of two assemblies hung on a wall;

FIG. 5A is a detailed view of area A shown in FIG. 5;

FIG. 5B1 is a detailed view of area B shown in FIG. 5;

FIG. 5B2 is an exploded view of detailed view B shown in FIG. 5;

FIG. 5C1 illustrates the connection of a photovoltaic cell to the assembly;

FIG. 5C2 is a detailed view of area C shown in FIG. 5C1; and,

FIG. 5D is an isometric view of a wall clad with the assemblies 10.

### DETAILED DESCRIPTION OF SPECIFIC EMBODIMENTS

Embodiments of the present invention provide a photovoltaic cell support assembly 10 that can be supported on a vertical wall and is able to support and electrically connect together a plurality of photovoltaic cells to thereby create a substantially vertical solar electric power generating wall. As explained in greater detail below, embodiments of the assembly 10 may be suspended by hooks only on the wall rather than being fixed by mechanical fasteners such as screws or nails to the wall. Embodiments of the assembly 10 may also be formed in a manner or from materials that provide thermal insulation and/or fire proofing.

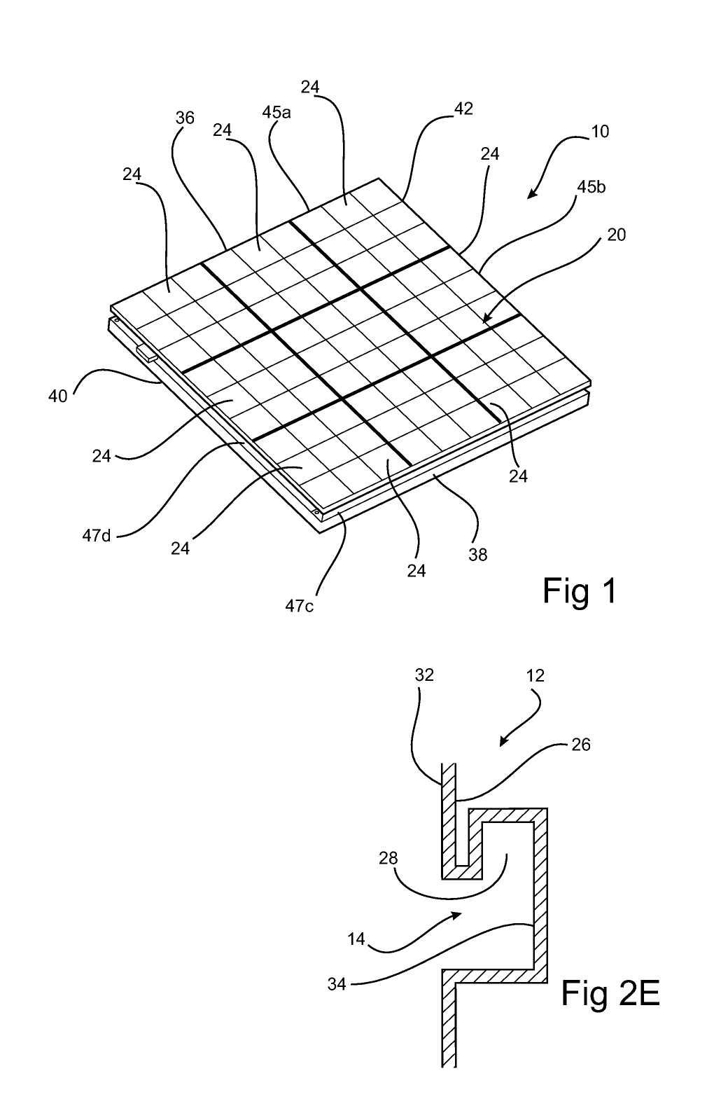

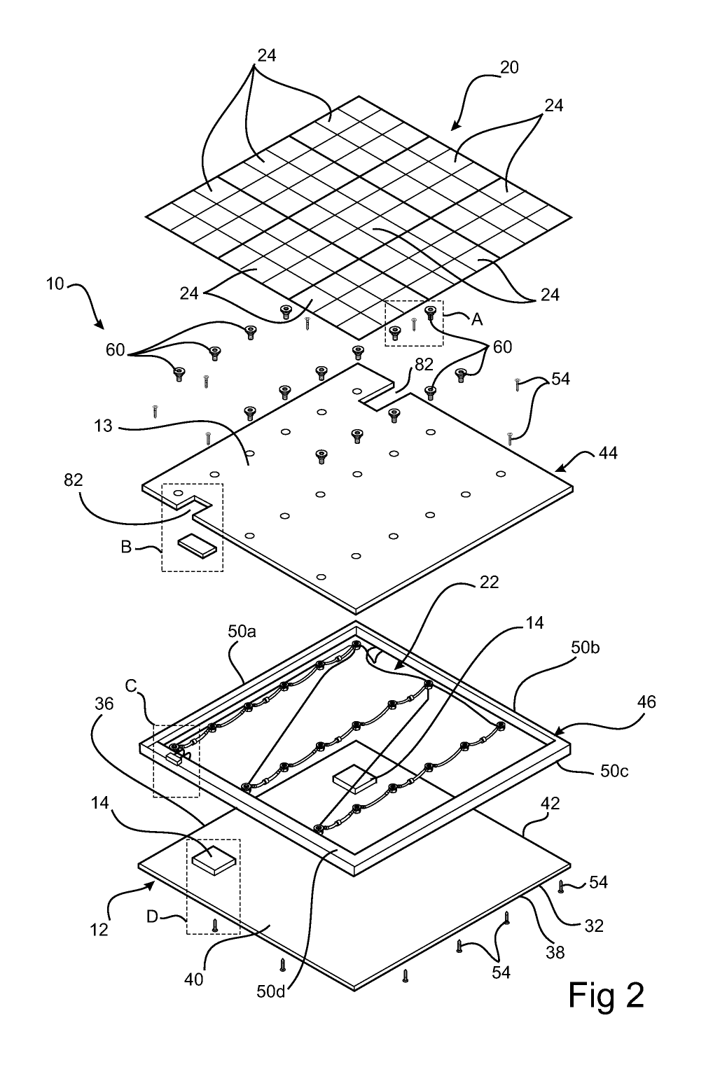

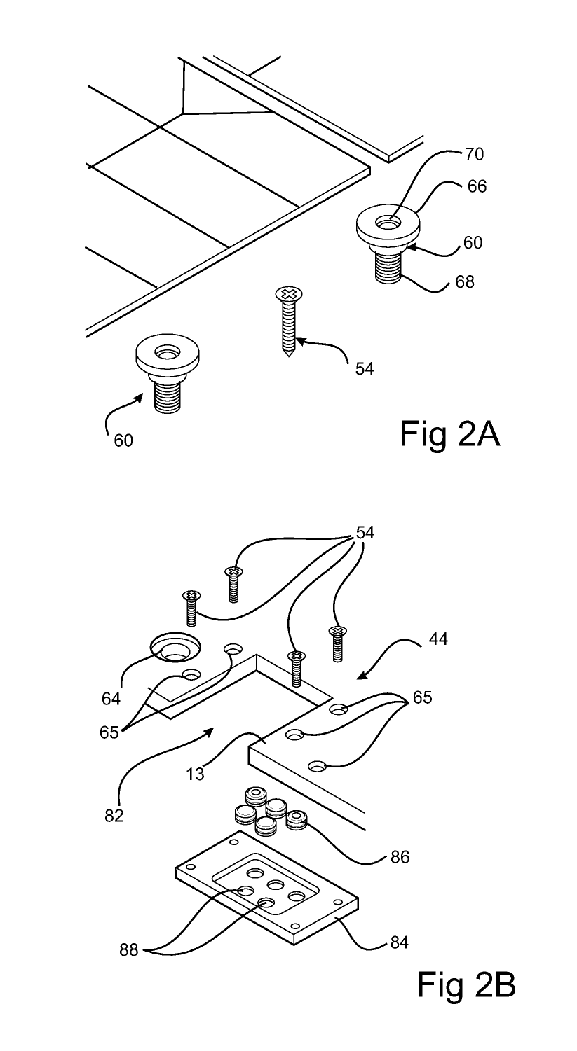

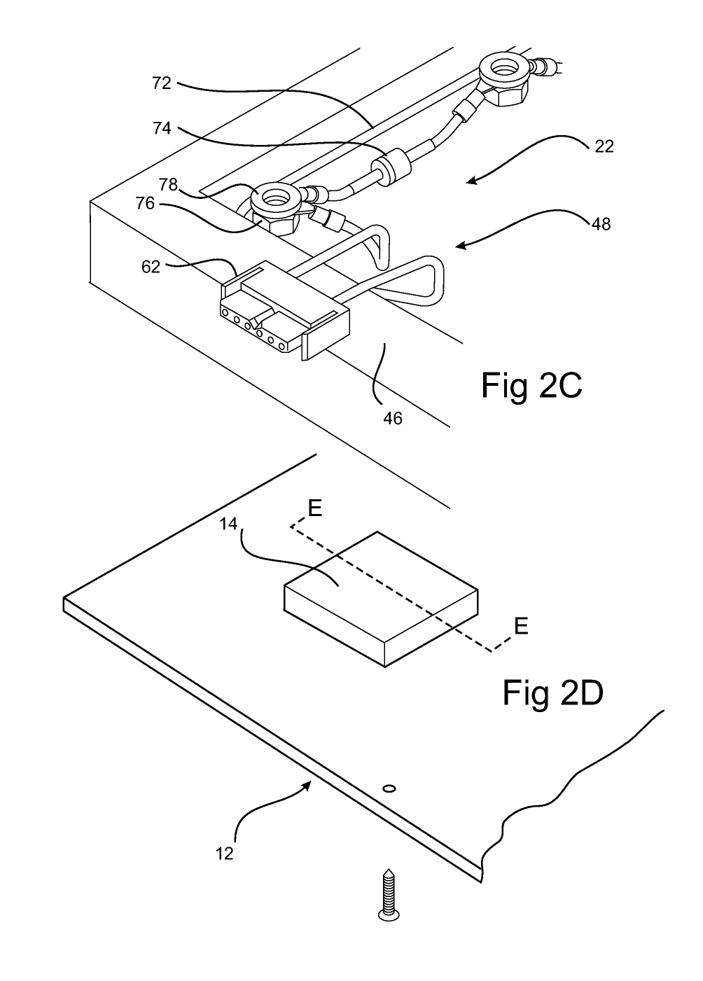

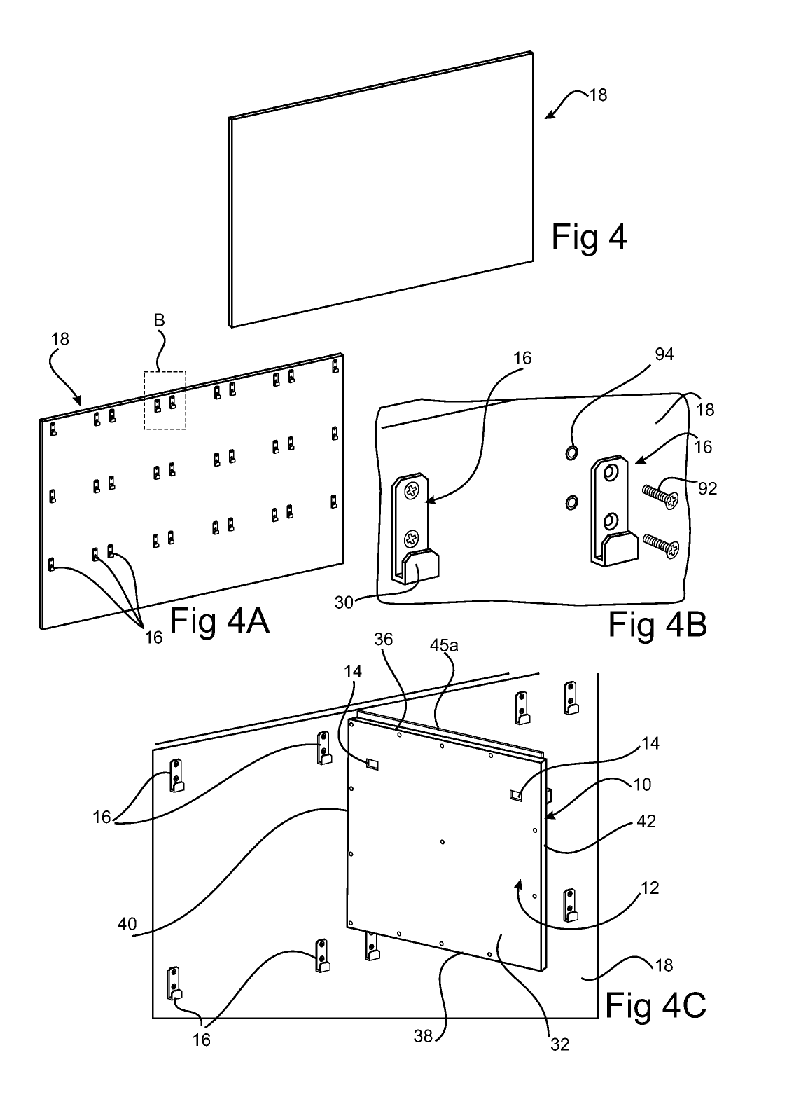

With reference to the accompanying drawings and in particular FIGS. 1 and 2, an embodiment of the photovoltaic cell support assembly (hereinafter referred to in general as “assembly”) 10 comprises a first surface 32 of a first panel 12 provided with one or more recesses (in this particular instance two recesses) 14 configured to receive respective hooks 16 (see FIGS. 4A-4C) to facilitate hanging of the assembly 10 on a wall 18, and a second surface 13 of a second panel 44 which is configured to couple with a plurality of photovoltaic cells 24. The assembly 10 also comprises an electric circuit 22 that electrically connects the photovoltaic cells 24 on a common panel 44 together as well as electrically connecting the assembly 10 to one or more adjacent assemblies 10. The cells 24 may be provided in a 3x3 array on photovoltaic panel 20.

The recess 14 is configured in a manner to prevent the flow of liquid such as rain into the interior of the assembly 10 through the recesses 14 when the assembly 10 is hung on the wall 18 by the hooks 16. One way of configuring the recess 14 in this manner is depicted in FIGS. 2D and 2E which show the recess 14 being formed integrally and continuously with the panel 12. More particularly, FIG. 2D shows a back side 26 of the first panel 12 where the recess 14 is formed as a depression in the panel 12 which is sealed in that it does not have any holes or openings through which liquid can flow. FIG. 2E illustrates a view of section E-E of FIG. 2D, through the recess 14. From the section view of it is seen that one form of the recess 14 comprises a socket 28 for receiving a tang 30 of a hook 16. FIG. 2E further shows that the first surface 32 which faces the wall 18 when the assembly 10 is hung on the wall 18 is continuous with a surface 34 of the recess 14.

As shown in FIGS. 2 and 4C, the recesses 14 lie on a common horizontal line which is parallel with an upper edge 36 of the panel 12. Recesses 14 are located substantially closer to the upper edge 36 than an opposite lower edge 38. In addition the recesses 14 are each located an identical distance inwardly of corresponding adjacent side edges 40 and 42 of the assembly 10.

Referring again to FIG. 2, the second panel 44 is coupled to the first panel 12 via an intervening frame 46. The frame 46 creates a space 48 between the panels 12 and 44 which contains a majority of the components of the electrical circuit 22.

The panels 12 and 44 may be attached to opposite sides of the frame 46 by a plurality of screws 54. A sealing gasket or sealing material (not shown) may be provided between the panels 12 and 44 and the frame 46 to minimise the likelihood of liquids such as water into the space 48.

The frame 46 comprises four members 50a, 50b, 50c and 50d (hereinafter referred to in general as “members 50”) which are joined together to form a square. Members 50a and 50b are adjacent each other forming a right angle as are members 50c and 50d. In this particular embodiment, the members 50a and 50b have a narrower width W1 than the width W2 of the members 50c and 50d. Each of the members 50 is provided with predrilled holes 52 for receiving the screws 54 for attaching the first and second panels 12 and 44 to the frame 46. In addition, the members 50a and 50c are each provided with a further threaded hole 56 near the member 50d. The holes 56 are provided on the side of the members 50a and 50c to which the second panel 44 is attached.

The panel 44 is offset from the frame 46 so that two edges of the panel 44 form lips 45a and 45b which over hang members 50a and 50b while leaving strips of the members 50c and 50d uncovered to form respective rebates 47c and 47d (see FIGS. 1, 3B and 5B2). The greater width W2 of the members 50c and 50d provides the room to enable the panel 44 to be fastened to these members while also providing area to form the rebates 47c and 47d.

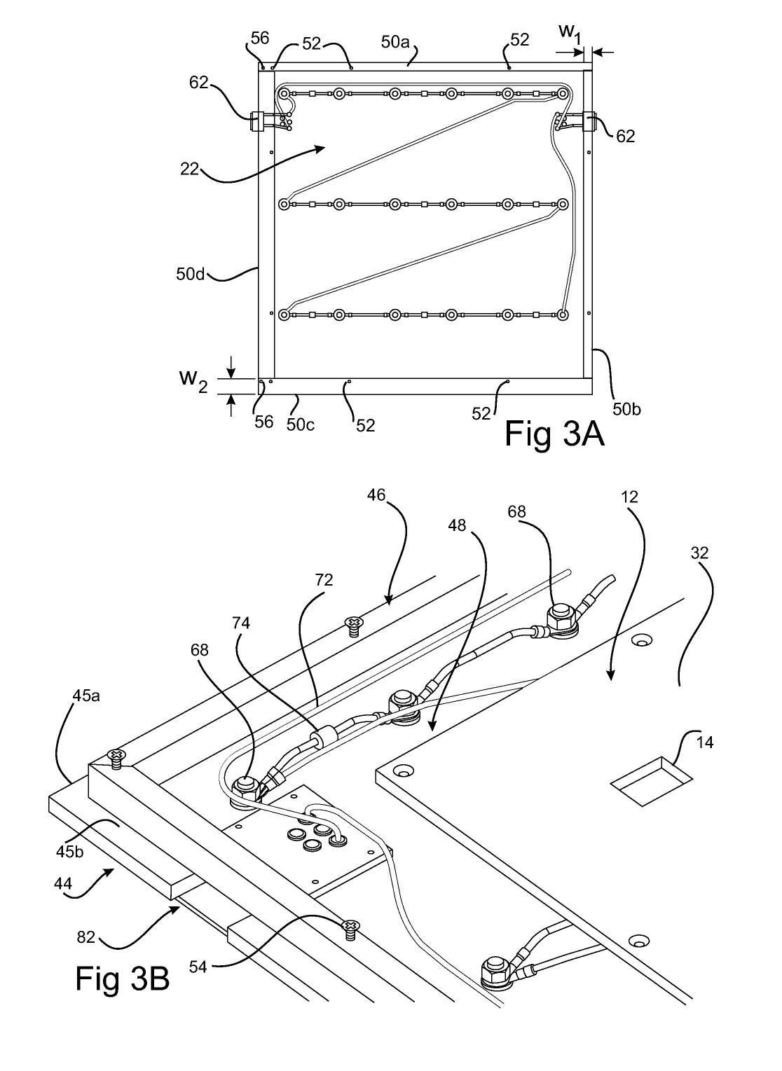

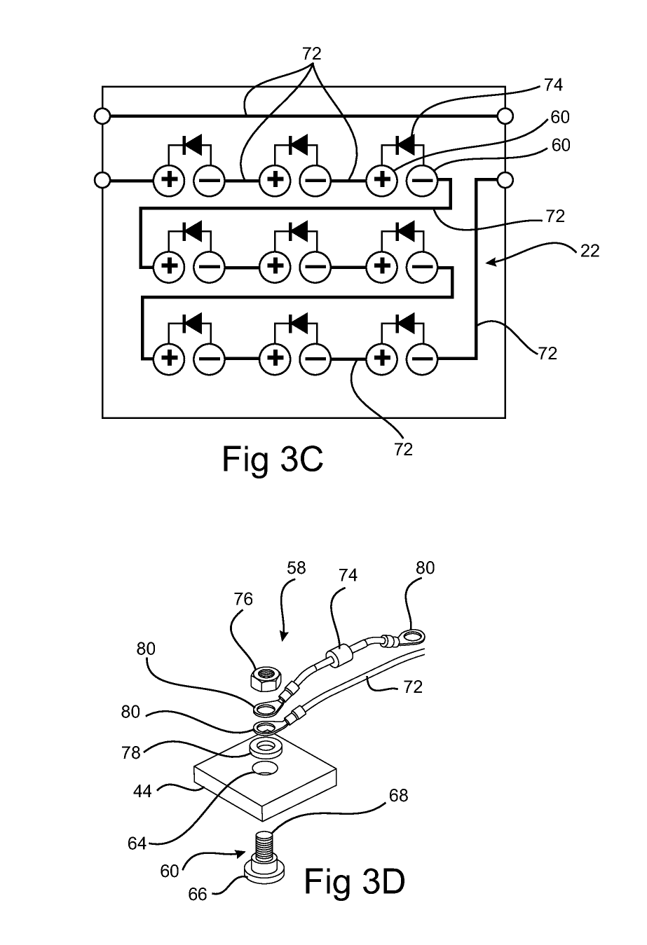

With reference to FIGS. 2C and 3A-3D, the electric circuit 22 comprises a sub-circuit 58 that is disposed between the panels 12 and 44, a plurality of electric terminals 60 that pass through the panel 44 into the space 48 between the panels 12 and 44; and, electrical plugs 62 that electrically connect with the sub-circuit 58. The terminals 60 pass through corresponding holes 64 formed in the panel 44 (see for example FIGS. 2, 3B and 3D).

The terminals 60 are in the form of studs or screws provided with a head 66 and a threaded shank 68. The head 66 is formed with an axial blind hole 70. The terminal 60 is made from an electrically conducting material. The holes 64 which receive the terminal 60 are counter-sunk on the surface 13 as shown most clearly in FIG. 2B so that the head 66 of the terminals 60 lie flush with or below the surface 13 of the second panel 44. Holes 65 for receiving the screws 54 are also counter sunk so the heads of screws 54 lie flush with or below the surface 13.

The sub-circuit 58 comprises a plurality of wires 72, diodes 74 and nuts 76. The wires 72, and leads from opposite ends of the diodes 74, are each provided with lugs 80 that are passed onto the shanks 68. To construct and connect the sub-circuit 58 initially the second panel 44 is fastened to the frame 46. The terminals 60 are then passed through the holes 64 so that their shanks 68 extend into the space 48. Washers 78 are then pushed onto the shanks 68. The washers 78 act as sealing washers to provide a seal against the ingress of foreign matter including liquid into the space 48. Next, the lugs 80 of the wires 72 and diodes 74 are placed onto the shanks 68. The lugs 80 are mechanically and electrically coupled to the terminals 60 by the nuts 76.

In order to provide physical space for the electrical plugs 62, the panels 44 are provided with two cut out 82 which open onto opposite side edges 40 and 42 of the assembly 10 (see for example FIGS. 2, 2B, 3B and 5A). Connector plates 84 are provided to allow wires 72 from the sub-circuit 58 to pass through the space 48 to the respective plugs 62. The connector plates 84 cover the cut outs 82 from a location inside of the frame 46 to an internal edge of the frame 46. This provides a seal against the ingress of matter into the space 48. Rubber grommets 86 are provided in holes 88 formed in the plate 84 to allow the passage of wires 72 from inside the space 48 to the plugs 62 while also providing a seal against the ingress of foreign matter into the space 48.

As shown in FIG. 3C, the sub-circuit 58 is configured to couple the photovoltaic cells 24 in series with diodes 74 shunted across the outputs of the photovoltaic cells 24. The shunting of the outputs of the photovoltaic cells 24 is achieved by connecting the diodes 74 across pairs of terminals 60 to which respective photovoltaic cells 24 are to be coupled.

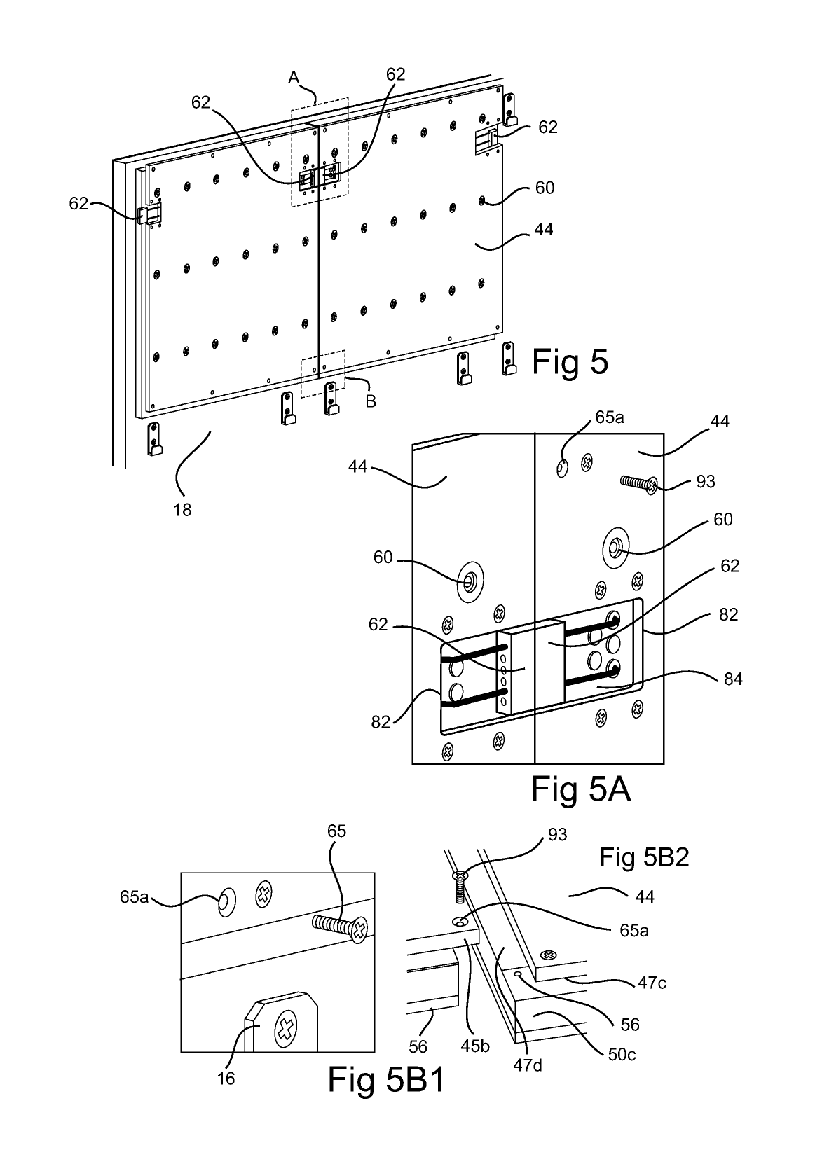

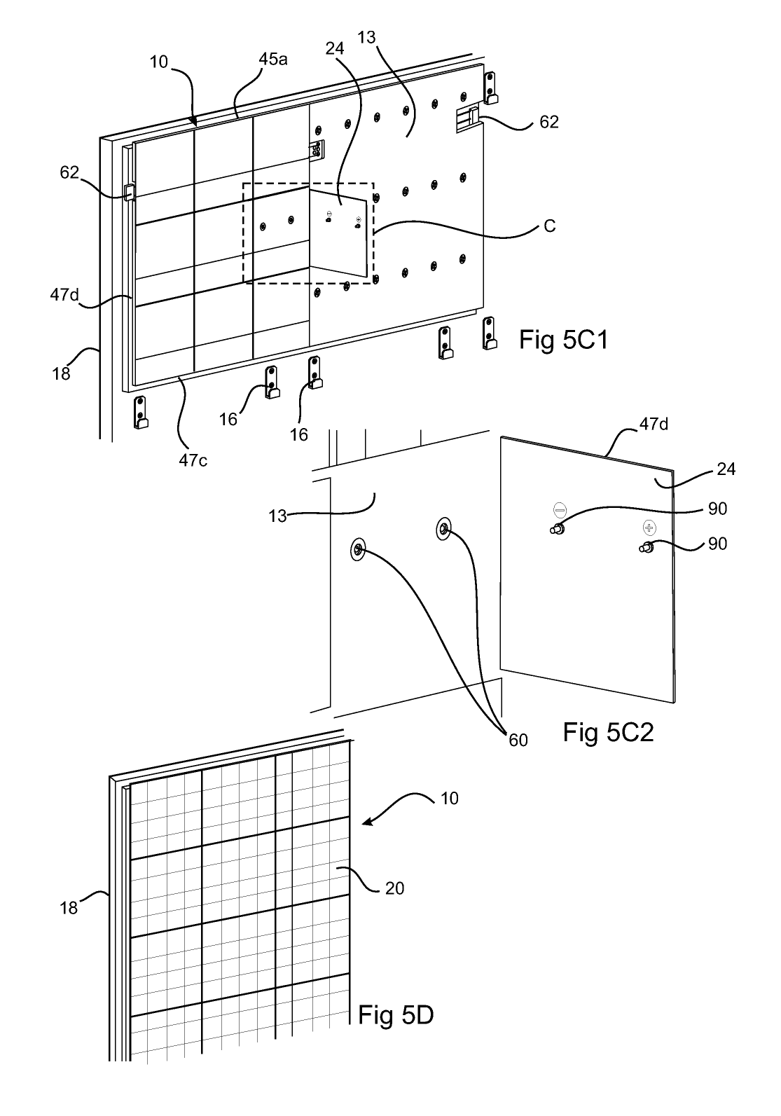

Referring to FIGS. 5A, 5C1 and 5C2, each photovoltaic cell 24 of a photovoltaic panel 20 is provided with a pair of electrical output connectors 90 that extend perpendicular to a plane of the cell 24. The terminals 60 are located on the second layer 44 at locations that register with the terminals 90.

Thus the cells 24 and corresponding photovoltaic panel 20 is electrically and mechanically coupled to the layer 44 by insertion of the connectors 90 into the blind holes 70 of the terminals 60. If desired, to provide greater mechanical attachment between the photovoltaic cells 24/panels 20 to the layer 44, and to also minimise the risk of foreign matter passing between the photovoltaic panel 20/cells 24 and the second panel 44, a bead of sealant material may be applied about the perimeter of the respective panels 20 and/or cells 24. The circuit 22 is also configured in this embodiment to provide a series connection between adjacent assemblies 10. The connection between adjacent assemblies 10 is made by engagement of plugs 62 of mutually adjacent assemblies 10 as shown in FIG. 5A.

A substantially vertical solar electric generating wall can be constructed by cladding the vertical wall 18 with a plurality of the assemblies 10 and attaching photovoltaic cells 24/panels 20 to the assemblies 10. This is achieved by initially fastening a plurality of hooks 16 onto a vertical face of the wall 18 using mechanical fasteners 92 appropriate for the particular wall 18 at hand. For example, if wall 18 is a masonry wall, then mechanical fasteners may comprise screws 92 and wall plugs 94 (see FIG. 4B). An assembly 10 is hung on the wall 18 by simply engaging the hooks 16 in the recesses 14. To continue constructing the wall, a second assembly 10 is hung on respective hooks 16 as shown in FIG. 5A. The respective electrical plugs 62 of the adjacent assemblies 10 are connected together. Sideways adjacent assemblies 10 may also be mechanically coupled by screwing lip 45b on a right hand edge 42 of the left most assembly 10 shown in FIG. 5 onto a rebate 47d formed on the left hand edge 40 of the adjacent right hand assembly 10. The holes 56 are provided along the rebate 47d at locations that register with corresponding holes 65a formed in the lip 45b of an adjacent assembly 10. Thus, shown in FIGS. 5A and 5B2, a left hand assembly 10 can be mechanically coupled to a right hand assembly 10 by seating the lip 45b in the rebate 47d and screwing a screw 93 through the hole 65a in the lip 45b into the underlying hole 56 in the frame 46. The lip 45a the upper edge 36 of one assembly 10 seats in the rebate 47c of an adjacent higher assembly 10. If desired, corresponding holes may be formed in the lip 45a and an underlying portion of the frame 46 in the rebate 47c to allow mechanical coupling of upper and lower adjacent assemblies 10.

Once all the assemblies 10 have been hung on the wall 18, respective photovoltaic panels 20/cells 24 can be attached to the respective assemblies 10 by engagement of the terminals 90 of the photovoltaic cells 24 in each photovoltaic panel 20 with the terminals 60 attached to the second panels 44 of the assemblies 10.

Electrical power generated by the photovoltaic panels 20 may be provided to an electrical load, switch or electrical management system which may include storage devices such as batteries or capacitors.

Throughout the description and drawings, example embodiments are given with reference to specific configurations. It will be appreciated by those of ordinary skill in the art that the present invention can be embodied in other specific forms. Those of ordinary skill in the art would be able to practice such other embodiments without undue experimentation. The scope of the present invention, for the purpose of the present patent document, is not limited merely to the specific example embodiments or alternatives of the foregoing description.

We claim:

1. A photovoltaic cell support assembly comprising:
a first surface provided with a plurality of recesses configured to receive respective hooks to facilitate hanging of the assembly to a wall to which the hooks are attached;
a second surface configured to mechanically and electrically couple with one or more photovoltaic cells; and,
an electric circuit supported by the assembly, the electrical circuit provided with a plurality of terminals that extend through the second surface to provide the mechanical and electrical coupling of the photovoltaic cells, the electric circuit configured to electrically connect the or each photovoltaic cell coupled to the second surface together and electrically connect the photovoltaic cladding assembly to a second like assembly.

2. The assembly according to claim 1 wherein each recess is configured to prevent flow of a liquid into the interior of the assembly from the recess when the assembly is hung on a wall by the hooks.

3. The assembly according to claim 1 or 2 wherein each recess is sealed to prevent flow of a liquid into an interior of the assembly from the recess when the assembly is hung on a wall by the hooks.

4. The assembly according to any one of claims 1-3 comprising a first panel wherein the first surface is a surface of the first panel which faces the wall when the assembly is hung on the wall, and wherein the recess comprises a recess surface which is continuous with the first surface.

5. The assembly according to any one of claims 1-4 comprising respective lips extending laterally from each of two edges of the assembly and respective rebates provided about each of two further edges of the assembly, the lips and rebates being relatively configured wherein the lips on the assembly can seat in rebates of two respective adjacent assemblies.

6. The assembly according to claim 5 wherein at least one of the lips is provided with a pre-formed hole for receiving a fastener, the hole located so that the fastener when applied through the hole couples the assembly to the rebate of an adjacent assembly.

7. The assembly according to any one of claims 1-6 comprising a second panel wherein the second surface is an exposed surface of the second panel and wherein the second panel is coupled to and spaced from the first panel.

8. The assembly according to claim 7 wherein the electrical terminals pass through the second layer and are provided with blind holes that open onto the second surface for receiving connectors of the photovoltaic cells.

9. The assembly according to claim 8 wherein the electrical circuit comprises a sub-circuit disposed in a space between the first panel and the second panel, the sub-circuit electrically connected to the electrical terminals and to electrical plugs, the electrical plugs facilitating electrical connection between adjacent assemblies.

10. The assembly according to claim 9 wherein the sub-circuit is configured to couple the photovoltaic cells of supported on a common second panel in series.

11. The assembly according to claim 10 wherein the sub-circuit comprises for each photovoltaic cell, a bypass diode coupled across the electrical terminals to which that photovoltaic cell is connected.

12. The assembly according to claim 10 or 11 wherein the electrical plugs are connected with the sub-circuits in a manner wherein adjacent assemblies are electrically coupled in series.

13. The assembly according to any one of claims 7-12 comprising a frame disposed between the first panel and the second panel, the frame spacing the first panel from the second panel.

14. The assembly according to claim 13 wherein the first and second panels are attached and sealed to the frame.

15. The assembly according to any one of claims 1-14 wherein the first panel is made of a thermally insulating material.

16. The assembly according to any one of claims 7-15 wherein the second panel is made of a thermal insulating material.

17. The photovoltaic cladding assembly according to any one of claims 1-16 wherein the first panel is made of a fire proof material.

18. The assembly according to any one of claims 7-17 wherein the second panel is made of a fireproof material.

19. A substantially vertical wall comprising:
a vertical wall surface;
a plurality of hooks fastened to the surface; and,
one or more assemblies according to any one of claims 1-18 wherein the or each assembly is hung on the wall by engagement of one or more of the hooks with one or more of the recesses of the assemblies.

20. The wall according to claim 19 comprising a plurality of photovoltaic cells provided with connectors that project perpendicular to a plane of the cells, wherein the photovoltaic cells are coupled to the assemblies by engagement of the connectors with the terminals.

21. A method of constructing a substantially vertical solar electrical power generating wall comprising:
constructing a substantially vertical wall;
cladding the wall with a plurality of assemblies according to any one of claims 1-18 by fastening a plurality of hooks on the wall, hanging the photovoltaic cladding assemblies on the hooks, and electrically connecting the assemblies together; and,
electrically and mechanically coupling a plurality of photovoltaic cells to the assemblies by insertion of connectors of the cells with the terminals of the assemblies.
